(19) United States
(12) Patent Application Publication
(10) Pub. No.: US 2004/0000675 A1
(43) Pub. Date: Jan. 1, 2004

(54) Method for manufacturing avalanche photodiodes, avalanche photodiode, optical receiver module and optical receiving apparatus

(75) Inventors: Hiroyuki Kamiyama, Saitama (JP); Takashi Toyonaka, Yokohama (JP)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: OpNext Japan, Inc., Yokohama-shi (JP)

(21) Appl. No.: 10/371,903

(22) Filed: Feb. 20, 2003

(30) Foreign Application Priority Data
May 24, 2002 (JP) 2002-151241
Nov. 1, 2002 (JP) 2002-319244

(51) Int. Cl. H01L 21/00; H01L 31/0328

(52) U.S. Cl. 257/184; 257/185; 257/186; 438/48; 257/447

(57) ABSTRACT

With respect to an avalanche photodiode (APD) having a semi-insulating re-grown guard-ring layer, its photocurrent-vs.-reverse-bias-voltage characteristic at several temperature-points is measured. Moreover, based on the measured result, the optical responsivity is determined from a flat portion that will appear in the photocurrent-vs.-reverse-bias-voltage characteristic at a temperature that is higher than the several temperature-points.

This application is a Continuation-in-Part of our U.S. patent application Ser. No. 224, 115 filed on Aug. 19, 2002.

### BACKGROUND OF THE INVENTION

The present invention relates to a method of manufacturing an avalanche photodiode in which there appears no flat portion in its photocurrent-vs.-reverse-bias-voltage characteristic at the room temperature, the avalanche photodiode, an optical receiver module, and an optical receiving apparatus.

The avalanche photodiode (which, hereinafter, will be abbreviated as “APD”) makes it possible to amplify, within the avalanche photodiode itself, the electric current generated by a signal light (Here, the magnitude of this amplification is referred to as “multiplication factor M”). This capability, when the APD is applied to an optical receiver, allows the reception sensitivity of the optical receiver to be high as compared with a PIN-photodiode that has no amplification function.

The execution of a pass/fail judgement on the optical coupling of the APD, or that of a control over the multiplication factor M requires the following task: The optical responsivity in the voltage region existing before the amplification is started should be determined and employed as the criterion. Based on this criterion, the main characteristics of the APD, i.e., the dynamic range (e.g., a 10-GHz band at M=3 to 10) and the like, are determined. Consequently, this optical responsivity at M=1 can be said to be an important element for the manufacturers in determining the specification of the optical receiver. Also, for the purchasers as well, the optical responsivity at M=1 becomes a criterion in carrying out the acceptance inspection. Accordingly, the purchasers need to be able to specify the optical responsivity at M=1.

In the diffusion-planar structure that has been used from conventionally as a structure of the APD, in its photocurrent-vs.-reverse-bias-voltage characteristic, there appears a region portion in which the photocurrent becomes substantially flat with respect to the bias-voltage. Also, it is common that, defining this flat portion as the region of M=1, the optical responsivity at M=1 is obtained from the photocurrent in this flat portion. This scheme has been illustrated in FIG. 2 in “APD Receiver Module for 10 Gbps”, “FUJITSU”, 51, 3, pp. 152-155 (May, 2000).

Meanwhile, in the buried-mesa structure APD, the low electric-conductivity in the semi-insulating layer prevents the carriers from being displaced. This condition makes it almost impossible that the flat portion will appear in its photocurrent-vs.-reverse-bias-voltage characteristic.

FIG. 1 is a graph for explaining the photocurrent-vs.-reverse-bias-voltage characteristics of the APDs. FIG. 1(b) illustrates the photocurrent-vs.-reverse-bias-voltage characteristic of the diffusion-planar structure APD, where, at the voltage 8 to 14 V, there has definitely appeared the flat portion. The use of this characteristic makes it easy to execute the pass/fail judgement on the optical coupling, or to set up the multiplication factor M. Meanwhile, the curve (a) in FIG. 1 illustrates a characteristic of the buried-mesa structure APD having the semi-insulating epitaxially re-grown layer (i.e., a highly resistive guard-ring layer), where there has appeared no flat portion. Consequently, it is impossible to define, as the criterion of M=1, the photocurrent in the flat portion which has been employed in the conventional method.

Incidentally, JP-A-6-232443 can be cited as an invention relating to a method of manufacturing the mesa structure APD. Also, although not admitted as prior art, there exists U.S. patent application Ser. No. 224, 115 as a related application incorporated herein by reference.

In the buried-mesa structure APD having the semi-insulating re-grown guard-ring layer, since there appears no flat portion in its photocurrent-vs.-reverse-bias-voltage characteristic, it has been difficult to obtain the photocurrent in the flat portion which provides the criterion of M=1. On account of this, the buried-mesa structure APD has a difficulty in executing the pass/fail judgement on the optical coupling of the device, or in setting up the multiplication factor M. This difficulty has become an obstacle to the practical and commercial use of the buried-mesa structure APD, despite the fact that the buried-mesa structure APD has an advantage of providing a lower dark-current and a higher-reliability as compared with the diffusion-planar structure APD.

### SUMMARY OF THE INVENTION

In order to solve the above-described problem, in the present invention, the photocurrent-vs.-reverse-bias-voltage characteristic is measured in such a manner that the measurement temperature is employed and defined as the characteristic-measuring parameter. From the characteristics thus measured, a flat region portion (i.e., a region in which a predetermined variation in the photocurrent is obtained within a predetermined voltage range) is obtained which will appear in the photocurrent-vs.-reverse-bias-voltage characteristic at a higher temperature. Next, the photocurrent in this flat region is defined as the criterion of M=1. Moreover, the optical responsivity at M=1 is determined from this photocurrent.

Not only for the manufacturers but also for the users, this method is an acceptable way of determining the optical responsivity at M=1. Accordingly, applying this method makes it easy to execute the pass/fail judgement on the optical coupling of the device, or to set up the multiplication factor. As a result, it becomes possible to obtain a method of manufacturing a preferable avalanche photodiode, the avalanche photodiode, an optical receiver module, and an optical receiving apparatus.

Other objects, features and advantages of the invention will become apparent from the following description of the embodiments of the invention taken in conjunction with the accompanying drawings.

### BRIEF DESCRIPTION OF THE DRAWINGS

FIG. 1 is a diagram for explaining the photocurrent-vs.-reverse-bias-voltage characteristic of the buried-mesa structure APD and that of the diffusion-planar structure APD at the room temperature;

FIG. 2 is a cross-sectional view of an APD that is an embodiment of the present invention;

FIG. 3 illustrates actually-measured values and simulation values of the voltage-differentiated-value-vs.-bias-voltage characteristics of the APD that is the embodiment of the present invention;

FIG. 4 illustrates actually-measured values of the voltage-differentiated-value-vs.-temperature characteristics of the APD that is the embodiment of the present invention;

FIG. 5 illustrates actually-measured values and simulation values of the photocurrent-vs.-reverse-bias-voltage characteristics of the APD that is the embodiment of the present invention;

FIG. 6 is a cross-sectional view of an APD that is another embodiment of the present invention;

FIG. 7 is a cross-sectional view of an APD that is still another embodiment of the present invention;

FIG. 8 is a block diagram for illustrating an optical receiver module that is an embodiment of the present invention; and

FIG. 9 is a block diagram for illustrating an optical receiving apparatus that is an embodiment of the present invention.

### DESCRIPTION OF THE EMBODIMENTS

Hereinafter, referring to the drawings, the explanation will be given below concerning the embodiments of the present invention.

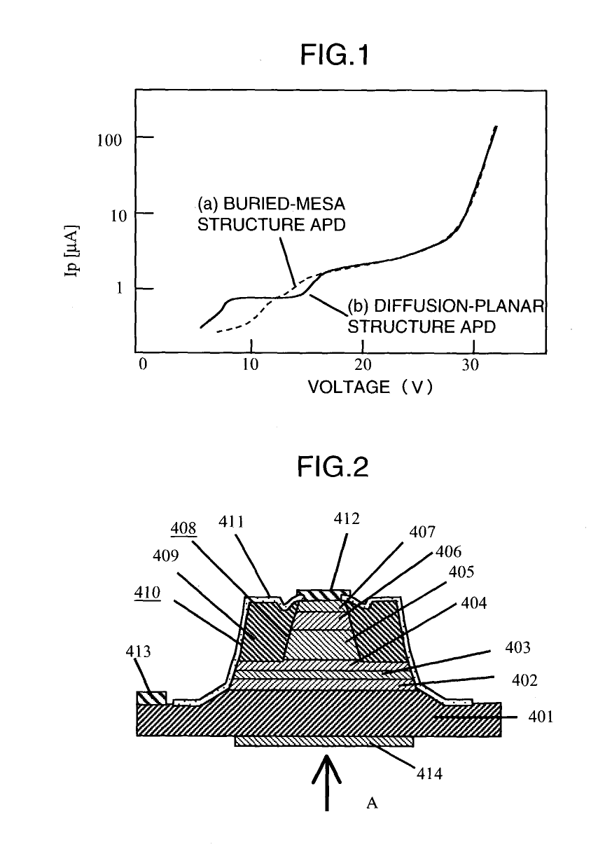

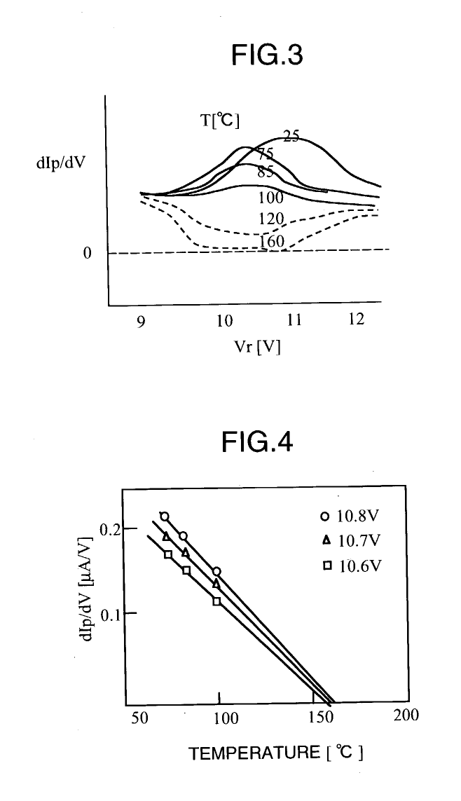

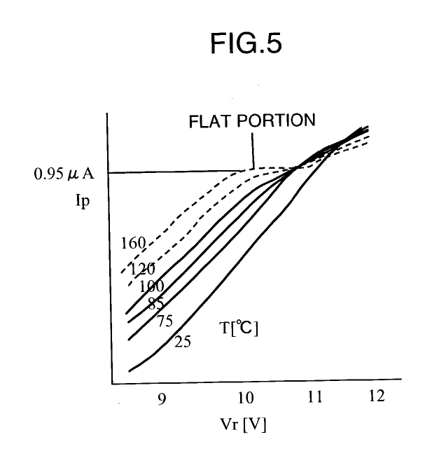

At first, referring to FIG. 1 and FIGS. 2 to 5, the explanation will be given below regarding a first mode of the present invention, i.e., an APD manufacturing method, and a second mode thereof, i.e., an APD embodiment. Here, a characteristic curved (a) in FIG. 1 is the illustrates the photocurrent-vs.-reverse-bias-voltage characteristic of the APD of the present invention. FIG. 2 is a cross-sectional view of the APD of the present invention. FIG. 3 is a diagram for illustrating the voltage-differentiated-photocurrent-value-vs.-bias-voltage characteristics of the APD of the present invention. FIG. 4 is a diagram for illustrating the voltage-differentiatedphotocurrent-value-vs.-measurement-temperature characteristics of the APD of the present invention where the voltage is employed and defined as the parameter. FIG. 5 is a diagram for illustrating the photocurrent-vs.-reverse-bias-voltage characteristics of the APD of the present invention which are actually measured at 25° C. to 100° C. and which are estimated at 120° C. and 160° C.

As illustrated in FIG. 2, the APD of this embodiment is manufactured as follows: First, the following layers are formed on an InP substrate 401 (n-type, 1E18 cm⁻³): An InAlAs buffer layer 402 (n-type, 1E18 cm⁻³, 0.5 μm), an InAlAs multiplication layer 403 (n-type, 1E14 cm³, 0.3 μm), an electric-field control layer 404 (p-type, 8E17 cm³, 0.04 μm) formed of an alternating layer of InAlAs and InGaAs, an InGaAs light absorption layer 405 (p-type, 1E15 cm⁻³, 1.3 μm), an InAlAs cap layer 406 (p-type, 3E18 cm⁻³, 0.7 μm), and an InGaAs contact layer 407 (p-type, 1E19 cm⁻³, 0.1 μm) Next, using a 30-μm-diameter SiO₂ mask, an etching is performed starting from the contact layer 407 until reaching a part of the electric-field control layer 404, thereby forming a first mesa 408. Then, an InP layer 409 (semi-insulating property, 1.8 μm), which becomes a re-grown layer, is grown on the periphery of the first mesa 408. Moreover, using a resist mask whose diameter is larger than that of the mask used for forming the first mesa 408, an etching is performed until reaching the InP substrate 401, thereby forming a second mesa 410. Furthermore, a SiN/SiO₂ passivation film 411 (0.2 μm/0.3 μm) is formed from the contact layer 407 all over to the outer-circumferential surface of the second mesa 410 and an exposed surface of the substrate 401. Still next, the passivation film 411 is removed from a part of the upper surface of the contact layer 407 and a part of the substrate 401, and then TiPtAu electrodes 412 and 413 (0.5 μm) are formed in the removed portions, respectively. A SiN antireflection coating film 414 (0.2 μm) is formed on the rear surface of the substrate 401. The above-described processing steps allow the APD to be manufactured. Incidentally, as is shown by the light-signal incoming direction indicated by the arrow A, this APD is a bottom-illuminated type whose incident surface is the portion of the SiN anti-reflection coating film 414.

Finally, giving consideration to the device estimation and the implementation into an optical receiver module, the bonding of each of the electrodes 412 and 413 is performed to each of electrodes corresponding to not-illustrated wiring substrate.

When applying a reverse bias-voltage to the APD of the present embodiment via the electrodes of the wiring substrate, the breakdown voltage has turned out to be 30 V, and the dark current has been found to be 20 nA at 27 V. These are quite satisfactory characteristics. Also, in the photocurrent-vs.-reverse-bias-voltage characteristic obtained when the APD is illuminated with a 1.55-μm-wavelength and 1-μW-power light at the room temperature (i.e., 25° C.), there appears no flat portion just like the case of FIG. 1 (a) and that of 25° C. in FIG. 5. Next, the solid lines in FIG. 5 indicate the results obtained by measuring the photocurrent-vs.-reverse-bias-voltage characteristic under a condition of setting up the measurement temperature as 75° C., 85° C., and 100° C. The solid lines in FIG. 3 indicate the results of the voltage-differentiated-photocurrent-value-vs.-bias-voltage characteristics determined using the measured results of the photocurrent-vs.-reverse-bias-voltage characteristic. FIG. 3 shows that the voltage-differentiated photocurrent value has a tendency to become smaller as the measurement temperature becomes higher. Here, the highest temperature out of the measurement temperatures (i.e., the upper-limit of the measurable temperature) has been set up as 100° C. This is because the upper-limit value of the temperature specification for the measurement is equal to 100° C.

FIG. 4 indicates the characteristic data obtained by organizing the above-described measured results further in terms of the voltage-differentiatedphotocurrent-value-vs.-measurement-temperature viewpoint where the voltage is employed and defined as the parameter. In FIG. 4, extrapolating the temperature to a higher-temperature region allows the simulation to be performed such that, at a temperature near 160° C. and at the voltage of 10.6 to 10.8 V, the voltage-differentiated photocurrent value becomes equal to 0 (namely, this corresponds to a flat portion in the photocurrent-vs.-reverse-bias-voltage characteristic). Based on a detailed investigation from FIG. 3 and FIG. 4, an estimate has been made concerning a temperature and a voltage range at and in which the voltage-differentiated photocurrent value becomes equal to 0. At 160° C., the voltage range has been estimated to be 9.8 to 11.0 V. FIG. 3 indicates, by the dashed lines, this simulated value with respect to 120° C. and 160° C. Also, the dashed lines in FIG. 5 indicate the photocurrent-vs.-reverse-bias-voltage characteristics determined using this simulated result. In FIG. 5, there appears a flat portion at 160° C., and accordingly the photocurrent in this flat portion can be defined as the criterion of the multiplication factor.

Namely, in FIG. 5, the photocurrent value at 160° C. and in the range of 9.8 to 11.0 V has been equal to 0.95 μA. This condition has allowed the optical responsivity at M=1 to be determined as 0.95 A/W.

The reason why the buried-mesa structure APD of the present embodiment exhibits the characteristics as described above is as follows: When the semi-insulating re-grown guard-ring layer is used in the buried-mesa structure APD, the electric-conductivity does not increase within the measurable temperature range (i.e., 25 to 100° C.). As a result, even if the light-receiving layer has been fully depleted, the optical carriers generated therein cannot pass through sufficiently in the electrodes' direction via the re-grown guard-ring layer. At this time, the main current path of the APD, where a part of the buffer layer has been not depleted, lies in a state of preventing the photocurrent from passing therethrough. Meanwhile, the analysis has been performed concerning the photocurrent-vs.-reverse-bias-voltage characteristic at the several temperature-points within the measurable temperature range. Based on this analysis, it has been found that, as shown in FIGS. 4 and 5, the voltage-differentiated photocurrent value approaches 0 within the specific voltage range at the temperature existing outside the assessable temperature range, thereby resulting in the appearance of the flat portion. This means the following situation: The temperature rise increases the carrier concentration in the semi-insulating re-grown layer, thereby raising the electric-conductivity. As a consequence, almost all the optical carriers within the light-receiving layer are permitted to pass through in the electrodes' direction via the re-grown guard-ring layer.

Incidentally, in the APD of the present embodiment, the photocurrent increase by the avalanche multiplication has occurred at the bias-voltage larger than 11 V, and the maximum multiplication factor has turned out to be 100. Also, according to the result of a high-temperature and reverse-bias current-carrying test (where 200° C. and 100 μA remain constant) for assessing the life-span of the avalanche photodiode, no change has been found until 1000 hours later in any one of the breakdown voltage, the dark current, and the multiplication factor. This is a quite satisfactory result.

The present embodiment has made it possible to execute the pass/fail judgement on the optical coupling, and also has made it easy to set up the multiplication factor. Accordingly, the present embodiment has allowed the implementation of the low dark-current and high-reliability APD and the manufacturing method thereof.

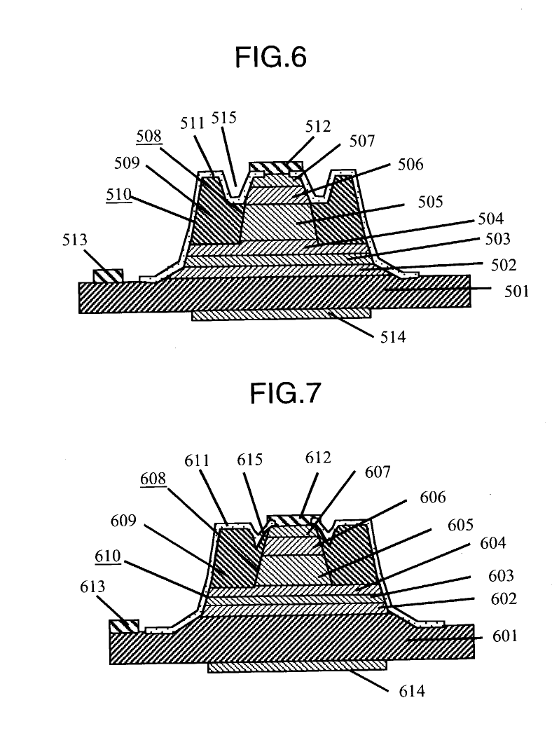

Next, referring to FIG. 6, the explanation will be given below concerning the first mode of the present invention, i.e., another APD manufacturing method, and the second mode thereof, i.e., another APD embodiment. Here, FIG. 6 is a cross-sectional view of another APD embodiment of the present invention.

As illustrated in FIG. 6, the APD of this embodiment is manufactured as follows: First, the following layers are formed on an InP substrate 501 (p-type, 1E18 cm⁻³) An InAlAs buffer layer 502 (p-type, 1E18 cm⁻³, 0.5 μm), an InAlAs multiplication layer 503 (p-type, 1E14 cm⁻³, 0.3 μm), an electric-field control layer 504 (n-type, 8E17 cm⁻³, 0.04 μm) formed of an alternating layer of InAlAs and InGaAs, an InGaAs light absorption layer 505 (n-type, 1E15 cm³, 1.4 μm), an InAlAs cap layer 506 (n-type, 3E18 cm⁻³, 0.7 μm), and an InGaAs contact layer 507 (n-type, 1E19 cm⁻³, 0.1 μM) Next, using a 30-μm-diameter SiO₂ mask, an etching is performed starting from the contact layer 507 until reaching a part of the electric-field control layer 504, thereby forming a first mesa 508. Then, an InP layer 509 (semi-insulating property, 1.9 μm), which becomes a re-grown layer, is grown on the periphery of the first mesa 508. Moreover, the SiO₂ mask is removed, and an etching is performed using a 24-μm-outer-diameter and 18-μm-inner-diameter resist mask that is concentric with the first mesa 508, thereby forming a concave-shaped portion 515 (about 1 μm deep and about 2 μm wide). Furthermore, using a resist mask whose diameter is larger than that of the mask used for forming the first mesa 508, an etching is performed until reaching the InP substrate 501, thereby forming a second mesa 510. Still next, a SiN/SiO₂ passivation film 511 (0.2 μm/0.3 μm thick) is deposited from the contact layer 507 all over to the outer-circumferential surface of the second mesa 510 and an exposed surface of the substrate 501. In addition, the passivation film 511 is removed from a part of the upper surface of the contact layer 507 and a part of the substrate 501, and then TiPtAu electrodes 512 and 513 (0.5 μm thick) are formed in the removed portions, respectively. A SiN anti-reflection coating film 514 (0.2 μm thick) is deposited on the rear surface of the substrate 501. The above-described processing steps allow the APD to be manufactured.

Giving consideration to the device estimation and the implementation into an optical receiver module, the bonding of each of the electrodes 512 and 513 is performed to each of electrodes corresponding to not-illustrated wiring substrate.

In the photocurrent-vs.-reverse-bias-voltage characteristic obtained when the APD is illuminated with the 1.55-μm-wavelength and 1-μW-power light, at the room temperature, there has appeared no definite flat portion as is the case with the embodiment described earlier. Then, the photocurrent-vs.-reverse-bias-voltage characteristic is measured at 75° C., 85° C., and 100° C. Next, based on the voltage-differentiated-photocurrent-value-vs.-bias-voltage characteristics, a simulation has been performed regarding a temperature and a voltage range at and in which the voltage-differentiated photocurrent value becomes equal to 0. The temperature and the voltage range have been found to be 150° C. and 10.5 to 12.0 V, respectively. The photocurrent value at this temperature and in this voltage range is equal to 0.95 μA. This condition has allowed the optical responsivity at M=1 to be specified as 0.95 A/W.

Also, in the APD of the present embodiment, the photocurrent increase by the avalanche multiplication has occurred at the bias-voltage larger than 12 V, and the maximum multiplication factor has turned out to be 90.

The present embodiment has made it possible to execute the pass/fail judgement on the optical coupling, and also has made it easy to set up the multiplication factor. Accordingly, the present embodiment has allowed the implementation of the low dark-current and high-reliability APD and the manufacturing method thereof.

Next, referring to FIG. 7, the explanation will be given below concerning the first mode of the present invention, i.e., still another APD manufacturing method, and the second mode thereof, i.e., still another APD embodiment. Here, FIG. 7 is a cross-sectional view of still another APD embodiment of the present invention.

The APD having the cross-sectional structure illustrated in FIG. 7 has been manufactured and assessed. The present embodiment, however, is the same as the embodiment in FIG. 2 except that the configurations of the portions at which the re-grown layer is in contact with the first mesa differ from each other.

In the growth of the re-grown layer of the present embodiment, by taking advantage of the growth restriction phenomenon on the periphery of a mask for selective growth, a concave-shaped portion 615 (1 μm deep) is formed on the periphery of the first mesa 608. The following layers are formed on an InP substrate 601 (n-type, 1E18 cm⁻³) An InAlAs buffer layer 602 (n-type, 1E18 cm⁻³, 0.5 μm), an InAlAs multiplication layer 603 (n-type, 1E14 cm⁻³, 0.3 μm), an electric-field control layer 604 (p-type, 8E17 cm⁻³, 0.04 μm) formed of an alternating layer of InAlAs and InGaAs, an InGaAs light absorption layer 605 (p-type, 1E15 cm⁻³, 1.3 μm), an InAlAs cap layer 606 (p-type, 3E18 cm⁻³, 0.7 μm), and an InGaAs contact layer 607 (p-type, 1E19 cm⁻³, 0.1 μm) Next, on the periphery of the first mesa 608, the concave-shaped portion 615 is formed in the InP layer 609 (semi-insulating property, 1.8 μm), i.e., the re-grown layer. Moreover, a passivation film 611 is removed from a part of the upper surface of the contact layer 607 and a part of the substrate 601, and then electrodes 612 and 613 are formed in the removed portions, respectively. An anti-reflection coating film 614 is deposited on the rear surface of the substrate 601.

The bonding of each of the electrodes 612 and 613 is performed to each of electrodes corresponding to not-illustrated wiring substrate. Then, when applying a reverse bias-voltage via the electrodes of the wiring substrate, the breakdown voltage has turned out to be 30 V. The dark currents at 15 V and 27 V have been found to be 0.1 nA and 15 nA, respectively. These are quite satisfactory values.

Also, in the photocurrent-vs.-reverse-bias-voltage characteristic obtained when the APD is illuminated with the 1.55-μm-wavelength and 1-μW-power light, at the room temperature, there has appeared no definite flat portion as is the case with the embodiment illustrated in FIG. 2. Then, the photocurrent-vs.-reverse-bias-voltage characteristic is measured at 75° C., 85° C., and 100° C. Next, based on the voltage-differentiated-photocurrent-value-vs.-bias-voltage characteristics, a simulation has been performed regarding a temperature and a voltage range at and in which the voltage-differentiated photocurrent value becomes equal to 0. The temperature and the voltage range have been found to be 160° C. and 9.8 to 11.0 V, respectively. The photocurrent value at this temperature and in this voltage range is equal to 0.95 μA. This condition has allowed the optical responsivity at M=1 to be specified as 0.95 A/W.

Also, in the present embodiment, the photocurrent increase by the avalanche multiplication has occurred at the bias-voltage larger than 11 V, and the maximum multiplication factor has turned out to be 100.

The present embodiment has made it possible to execute the pass/fail judgement on the optical coupling, and also has made it easy to set up the multiplication factor. Accordingly, the present embodiment has allowed the implementation of the low dark-current and high-reliability APD and the manufacturing method thereof.

Incidentally, in any one of the above-described embodiments, the InGaAs and InAlAs system has been employed as the multi-layered crystal, and InP has been employed as the re-grown layer. It is needless to say, however, that the other crystal systems can be freely employed. The examples are as follows: 2-dimemsional system such as InP and GaAs, 4-dimemsional system such as InGaAsP and InAlGaAs, or the like as the multi-layered crystal, GaAs, InAlAs, GaAlAs, InAlGaAs, InGaAsP, or the like in addition to InP as the re-grown layer, and a combination of p-type and n-type, a concentration thereof, or the like as the layer structure. Moreover, although the above-described embodiments are of the bottom-illuminated type, the incident surface of a light signal is not limited thereto but is freely selectable. The examples are as follows: A structure that the incident surface is the top-surface of the device, a structure that the incident surface is the side-surface thereof, or the like.

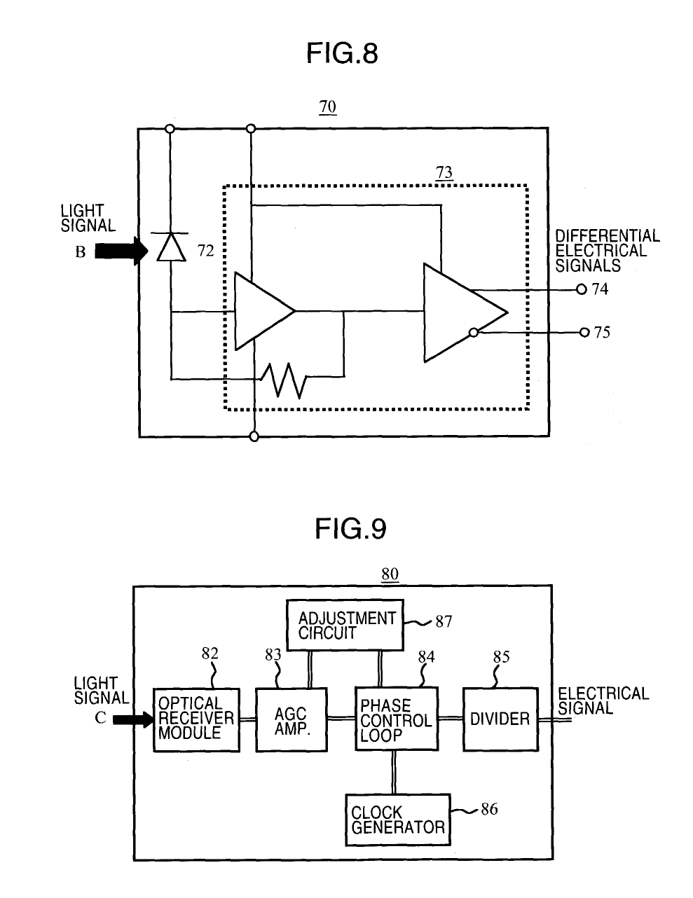

Next, referring to FIG. 8, the explanation will be given below concerning a third mode of the present invention, i.e., an optical receiver module. Here, FIG. 8 is a block diagram of the optical receiver module.

As illustrated in FIG. 8, the optical receiver module 70 mainly includes an APD 72 and a preamplifier 73, and is located within a not-illustrated housing. Also, if a light signal is launched into the module from the direction indicated by the arrow B, differential electrical signals 74 and 75 will be outputted.

In the photocurrent-vs.-reverse-bias-voltage characteristic of the APD 72, there has appeared no definite flat portion at the room temperature. Then, the photocurrent-vs.-reverse-bias-voltage characteristic is measured at 75° C., 85° C., and 100° C. Next, based on the voltage-differentiated-photocurrent-value-vs.-bias-voltage characteristics, an estimate has been made regarding a temperature and a voltage range at and in which the voltage-differentiated photocurrent value becomes equal to 0. The temperature and the voltage range have been found to be 160° C. and 10.6 to 11.8 V, respectively. The photocurrent value at this temperature and in this voltage range is equal to 0.85 μA. This condition has allowed the optical responsivity at M=1 to be specified as 0.85 A/W. Furthermore, the multiplication factors at the respective voltages have been determined from this optical responsivity, then measuring a 3-dB band of the optical receiver module at M=10. The 3-dB band and the manufacture variation therein have been found to be 8.8 GHz and 8.5±0.5 GHz, respectively. Also, measuring the minimum reception sensitivity has resulted in −28 dBm. This condition has made it possible to confirm that the optical receiver module operates satisfactorily enough as a 10-Gbit/s-use optical receiver module and satisfies the specification. The optimum multiplication factor at this time and the manufacture variation in the optimum multiplication factor have turned out to be 12 and 12±0.5, respectively.

In addition, the conventional diffusion-planar structure APD, in which there appears the flat portion in its photocurrent-vs.-reverse-bias-voltage characteristic at the room temperature, has been applied to the optical receiver module 70 for making the comparison. In this case, the manufacture variation in the 3-dB band at M=10 and the manufacture variation in the optimum multiplication factor have turned out to be 7.5±0.5 GHz and 14±0.5, respectively.

This condition has made it possible to confirm that the present-invention method of specifying the optical responsivity at M=1 exhibits a high-accuracy equivalent to the accuracy obtained when applying the conventional structure APD.

The present embodiment has allowed the implementation of the preferable low dark-current and high-reliability optical receiver module.

Next, referring to FIG. 9, the explanation will be given below concerning a 4th mode of the present invention, i.e., the embodiment of an optical receiving apparatus. Here, FIG. 9 is a block diagram of the optical receiving apparatus.

In the optical receiving apparatus 80 in FIG. 9, a light signal indicated by the arrow C is launched into the optical receiver module 82 explained in the above-described embodiment. At the back stage of the optical receiver module 82, there are incorporated an auto-gain-control amplifier (hereinafter, referred to as “AGC amplifier) 83, a phase control loop 84, a divider circuit 85, a clock generator 86, and an adjustment circuit 87. The electrical signal will be outputted from the divider circuit 85. Incidentally, the AGC amplifier 83 includes a memory (not illustrated) into which a control program is writable. Also, the AGC amplifier 83 has a following function: Depending on how large the light input level is, i.e., the electrical signal level inputted into the AGC amplifier from the optical receiver module is, the information of the output voltage level is fed back to the bias circuit of the APD device incorporated into the optical receiver module, and the bias-voltages applied to the APD device, i.e., the multiplication factor is controlled. Thereby, the output signal level from the optical receiving apparatus itself is maintained at a constant level regardless of how large the light input level is.

The optical responsivity of the optical receiver module 82 at M=1 has been specified as 0.85 A/W by using the optical responsivity specifying method of the present invention. The multiplication factors at the respective voltages have been determined from this optical responsivity. Moreover, in the AGC amplifier 83, the voltage values, i.e., the multiplication factors, are assigned depending on the light input level. The programming has been performed so that the optimum multiplication factor will becomes equal to 12 near the minimum light input −27 dBm.

Measuring the minimum reception sensitivity of the optical receiving apparatus has resulted in 27.5 dBm. This condition has made it possible to confirm that the optical receiving apparatus operates satisfactorily enough as a 10-Gbit/s-use optical receiving apparatus and satisfies the specification. In this optical receiving apparatus, the variation in the optimum multiplication factor is equal to 12±0.5, which is considerably small. This condition has made it easy to perform the programming regarding the AGC amplifier 83.

In the conventional diffusion-planar structure APD, there appears the flat portion in its photocurrent-vs.-reverse-bias-voltage characteristic at the room temperature. The optical receiver module into which this conventional diffusion-planar structure APD is incorporated has been applied to the optical receiving apparatus 80 for making the comparison. Then, the programming has been performed regarding the AGC amplifier so that the optimum multiplication factor will becomes equal to 14 near the minimum light input −25 dBm. Measuring the minimum reception sensitivity of the optical receiving apparatus has resulted in −25.3 dBm. This condition has made it possible to confirm that this optical receiving apparatus operates as the 10-Gbit/s-use optical receiving apparatus although the minimum reception sensitivity is inferior to some extent.

This condition has made it possible to confirm that the present-embodiment method of specifying the optical responsivity at M=1 exhibits a high-accuracy that can stand comparison with the accuracy obtained when applying the conventional structure APD.

The present embodiment has allowed the implementation of the preferable low dark-current and high-reliability optical receiving apparatus.

Incidentally, although, in the above-described embodiment, the control over the AGC amplifier 83 is performed by the control program written into the memory, this control can also be performed by hardware.

Conventionally, the conventional optical responsivity specifying method has been inapplicable to the APD having the semi-insulating re-grown guard-ring layer. This is because the flat portion in its photocurrent-vs.-reverse-bias-voltage characteristic is indefinite in the assessable temperature range. The present invention has been successful in providing the optical responsivity specifying method with respect to the APD like this, the optical receiver module, and the optical receiving apparatus. This has made it easy to execute the pass/fail judgement on the optical coupling, and has implemented a high-accuracy set-up of the multiplication factor. As a result, it has become possible to provide, at low-prices, the low dark-current and high-reliability buried-mesa structure APD, and the high-sensitivity and high-performance optical receiver module and optical receiving apparatus that employ this APD.

It should be further understood by those skilled in the art that although the foregoing description has been made on embodiments of the invention, the invention is not limited thereto and various changes and modifications may be made without departing from the spirit of the invention and the scope of the appended claims.

What is claimed is:

1. A method of manufacturing an avalanche photodiode, said method comprising the steps of:
obtaining a first photocurrent-vs.-voltage characteristic at a first temperature;
obtaining a second photocurrent-vs.-voltage characteristic at a second temperature;
obtaining a third photocurrent-vs.-voltage characteristic at a temperature higher than said first temperature and said second temperature by using said first photocurrent-vs.-voltage characteristic and said second photocurrent-vs.-voltage characteristic; and
obtaining, from said third photocurrent-vs.-voltage characteristic, the optical responsivity in a multiplication factor that becomes a criterion.

2. An avalanche photodiode in which there appears no flat portion in its photocurrent-vs.-voltage characteristic at the room temperature, said avalanche photodiode comprising:
a semi-insulating re-grown layer, wherein the optical responsivity in a multiplication factor that becomes a criterion is obtained from a photocurrent-vs.-voltage characteristic at a temperature exceeding 100° C.

3. The avalanche photodiode as claimed in claim 2, further comprising:
an InAlAs buffer layer;
an InGaAs light absorption layer; and
an InP semi-insulating re-grown layer.

4. An optical receiver module, comprising:
an avalanche photodiode in which there appears no flat portion in its photocurrent-vs.-voltage characteristic at the room temperature;
a pre-amplifier for amplifying an electrical signal resulting from photoelectric conversion performed by said avalanche photodiode; and
a housing for locating therein said avalanche photodiode and said pre-amplifier,
wherein the optical responsivity of said avalanche photodiode in a multiplication factor that becomes the criterion is obtained based on said photocurrent-vs.-voltage characteristic at a temperature exceeding 100° C.

5. An optical receiving apparatus including an optical receiver module and an auto-gain-control amplifier,
wherein said optical receiver module includes an avalanche photodiode and a housing for containing said avalanche photodiode,
the optical responsivity of said avalanche photodiode in a multiplication factor that becomes a criterion being obtained based on its photocurrent-vs.-voltage characteristic at a temperature exceeding 100° C.

6. The optical receiving apparatus as claimed in claim 5, wherein said auto-gain-control amplifier controls said optical receiver module so that the multiplication factors will be assigned depending on the light input level.
